(19) United States
(12) Patent Application Publication
(10) Pub. No.: US 2022/0052224 A1
(43) Pub. Date: Feb. 17, 2022

(54) LIGHT-EMITTING DIODE, MANUFACTURING METHOD THEREOF AND DISPLAY

(71) Applicant: CHONGQING KONKA PHOTOELECTRIC TECHNOLOGY RESEARCH INSTITUTE CO., LTD., Chongqing (CN)

(72) Inventors: Chia-Hung HUANG, Chongqing (CN); Kuo-Tung HUANG, Chongqing (CN)

(21) Appl. No.: 17/488,890

(22) Filed: Sep. 29, 2021

Related U.S. Application Data
(63) Continuation of application No. PCT/CN2020/108723, filed on Aug. 12, 2020.

(51) Int. Cl. H01L 33/06; H01L 25/075; H01L 33/50; H01L 33/32; H01L 33/00

(52) U.S. Cl. CPC H01L 33/06; H01L 25/0753; H01L 2933/0041; H01L 33/32; H01L 33/007; H01L 33/502

(57) ABSTRACT

A light emitting diode (LED) is provided in the disclosure. The LED includes a first contact electrode, a first semiconductor layer, a light emitting layer, a second semiconductor layer, a current diffusion layer and a second contact electrode that are successively stacked. Multiple micro-structures extend through the light emitting layer and the second semiconductor layer in a stacking direction of the light emitting layer and the second semiconductor layer, where the multiple micro-structures each defines a borehole space. The borehole space has opposite ends which are respectively closed by the first semiconductor layer and the current diffusion layer. Quantum dots are filled in the borehole space of the multiple micro-structures. Lights of corresponding colors are emitted by exciting corresponding quantum dots with a part of blue lights emitted by the micro-structures.

### CROSS-REFERENCE TO RELATED APPLICATIONS

This application is a continuation of International Application No. PCT/CN2020/108723, filed on Aug. 12, 2020, the entire disclosure of which is incorporated herein by reference.

### TECHNICAL FIELD

This disclosure relates to the technical field of semiconductors, and more particularly to a light emitting diode (LED), a manufacturing method for the LED and a display with the LED.

### BACKGROUND

An LED is a semiconductor device that can convert electrical energy into light energy. The LED has a general structure with an epitaxial substrate, a light emitting unit formed on the epitaxial substrate, and an electrode unit that can provide electrical energy to the light emitting unit. When the electrical energy is provided to the light-emitting unit via the electrode unit from outside, the light emitting unit will emit light outward. Currently, a gallium nitride (GaN) based LED receives more and more attention and research. For example, the light emitting unit is made by growing GaN in an epitaxial manner on the epitaxial substrate made from a sapphire. Therefore, a display with the above-mentioned LED is relatively mature in developments of a material, a process, a device, and other aspects, and can be used in a wide range of application fields, which becomes a highly feasible next-generation flat panel display technology.

At present, there are two methods to apply the above-mentioned LED to the display: (1) using red-green-blue (RGB) LEDs for natural color mixing; (2) using quantum dots and blue LEDs of the display. However, if using the above-mentioned method (1), it may be difficult in a circuit design of a display panel; if using the above-mentioned method (2), there usually exists a problem that color conversion efficiency of quantum dots is not high, resulting in low full-color efficiency. Therefore, how to improve the color conversion efficiency of the quantum dots has been a development direction for those skilled in the art.

### SUMMARY

Considering disadvantages of the above-mentioned related art, in this disclosure, an epitaxial substrate, a light emitting diode (LED), and a manufacturing method for the LED are provided.

The LED includes a first contact electrode, a first semiconductor layer, a light emitting layer, a second semiconductor layer, a current diffusion layer, and a second contact electrode that are successively stacked, multiple micro-structures, and quantum dots. The first contact electrode is in contact with and is connected with the first semiconductor layer, and the second contact electrode is in contact with and is connected with the current diffusion layer. Multiple micro-structures extend through the light emitting layer and the second semiconductor layer in a stacking direction of the light emitting layer and the second semiconductor layer. The multiple micro-structures each defines a borehole space. The borehole space has opposite ends which are respectively closed by the first semiconductor layer and the current diffusion layer. A quantum dot is filled in the borehole space of each of the multiple micro-structures.

Based on the same inventive concept, a manufacturing method for a LED is provided in the disclosure. The method includes the following. A substrate layer is provided. A first semiconductor layer is grown on the substrate layer. A light emitting layer is grown on the first semiconductor layer. A second semiconductor layer is grown on the light emitting layer. Multiple micro-structures are manufactured in the light emitting layer and the second semiconductor layer and a quantum dot is filled in the micro-structure. A current diffusion layer and a second contact electrode are grown successively on the second semiconductor layer and the quantum dots are closed in the multiple micro-structures. The substrate layer is removed and a first contact electrode is plated on a location of the first semiconductor layer corresponding to the substrate layer.

Based on the same inventive concept, a display is provided in the disclosure. The display includes a display panel and multiple LEDs, where the multiple LEDs are fixed on the display panel and are electronically coupled with the display panel.

### BRIEF DESCRIPTION OF THE DRAWINGS

In order to describe technical solutions of implementations more clearly, the following will give a brief introduction to the accompanying drawings used for describing implementations. Apparently, the accompanying drawings hereinafter described are some implementations of the disclosure. Based on these drawings, those of ordinary skill in the art can also obtain other drawings without creative effort.

FIG. 1 is a schematic cross-sectional view of a light emitting diode (LED) according to implementations.

FIG. 2a is a schematic top view of a micro-structure as illustrated in FIG. 1 according to implementations.

FIG. 2b is a schematic top view of a micro-structure as illustrated in FIG. 1 according to other implementations.

FIG. 2c is a schematic top view of a micro-structure as illustrated in FIG. 1 according to other implementations.

FIG. 3 is a schematic flowchart illustrating a manufacturing method for the LED of FIG. 1.

FIG. 4a-FIG. 4g are schematic structural diagrams corresponding to operations in the manufacturing method of FIG. 3.

FIG. 5 is a schematic flowchart illustrating block S10 in the manufacturing method of FIG. 3.

FIG. 6 is a schematic flowchart illustrating block S50 in the manufacturing method of FIG. 3.

FIG. 7 is a schematic cross-sectional view of a display with the above-mentioned LED according to implementations.

Reference numbers in the figures are illustrated as follows.

100: an LED; 10: a first contact electrode; 20: a first semiconductor layer; 30: a light emitting layer; 31: multiple quantum well layers; 31a: green indium gallium nitride (InGaN) quantum well layers; 31b: blue InGaN quantum well layers; 33: multiple quantum barrier layers; 50: a second semiconductor layer; 60: a current diffusion layer; 70: a second contact electrode; 80: a micro-structure; 82: a first borehole; 84: a second borehole; 85: a stopping wall; 86: a quantum dot; S10-S70: operations of the manufacturing method; S11-S13: sub-operations of operations at block S10; S51-S53: sub-operations of operations at block S50; 200: a display; 201: a sapphire substrate; 202: a buffer layer; 203: a undoped gallium nitride (GaN) layer; 210: a display panel; 212: an anode bonding pad; 213: a cathode bonding pad.

### DETAILED DESCRIPTION

In order to understand the present disclosure, a detailed description will now be given with reference to the relevant accompanying drawings. The accompanying drawings illustrate better examples of implementations of the present disclosure. However, the present disclosure can be implemented in many different forms and is not limited to the implementations described herein. On the contrary, these implementations are provided for a more thorough and comprehensive understanding of the present disclosure.

Unless otherwise defined, all technical and scientific terms used herein have the same meaning as commonly understood by those skilled in the art of the present disclosure. The terms used herein in the disclosure are for the purpose of describing specific implementations only and are not intended to limit the disclosure.

A light emitting diode (LED) has a general structure with an epitaxial substrate, a light-emitting unit grown on the epitaxial substrate, and an electrode unit that can provide electrical energy to the light emitting unit. When the electrical energy is provided to the light emitting unit via the electrode unit from outside, the light emitting unit will emit light outward. Currently, a gallium nitride (GaN) based LED receives more and more attention and research. For example, the light-emitting unit is made by growing GaN in the epitaxial manner on an epitaxial substrate made from a sapphire. Therefore, a display with the above-mentioned LED is relatively mature in developments of a material, a process, a device, and other aspects, and can be used in a wide range of application fields, which becomes a highly feasible next-generation flat panel display technology. At present, there are two methods to apply the above-mentioned LED to the display: (1) using red-green-blue (RGB) LEDs for natural color mixing; (2) using quantum dots and blue LEDs of the display. However, if using the above-mentioned method (1), it may be difficult in a circuit design of a display panel; if using the above-mentioned method (2), there usually exists a problem that color conversion efficiency of quantum dots is not high, resulting in low full-color efficiency.

Based on the above, a method which can solve the above-mentioned technical problems is provided according to the disclosure. Considering disadvantages of the above-mentioned related art, in this disclosure, an epitaxial substrate, a light emitting diode (LED), and a manufacturing method for the LED are provided, which is possible to solve a difficulty in a circuit design of a display panel and a problem that color conversion efficiency of quantum dots is not high in the related art.

The LED includes a first contact electrode, a first semiconductor layer, a light emitting layer, a second semiconductor layer, a current diffusion layer, and a second contact electrode that are successively stacked, multiple micro-structures, and quantum dots. The first contact electrode is in contact with and is connected with the first semiconductor layer, and the second contact electrode is in contact with and is connected with the current diffusion layer. Multiple micro-structures extend through the light emitting layer and the second semiconductor layer in a stacking direction of the light emitting layer and the second semiconductor layer. The multiple micro-structures each defines a borehole space. The borehole space has opposite ends which are respectively closed by the first semiconductor layer and the current diffusion layer. A quantum dot (or multiple quantum dots) is filled in the borehole space of each of the multiple micro-structures.

The above-mentioned LED, corresponding quantum dots are filled in borehole spaces defined in the micro-structures, and the corresponding quantum dots are excited, with a part of blue lights emitted by the micro-structures, to emit lights of corresponding colors, for example, red lights, or green lights, such that the light emitting layer may mix for white lights. Additionally, the corresponding quantum dots are filled in borehole spaces of the micro-structures, therefore, the micro-structures will improve color conversion efficiency due to a surface area effect, furthermore, improve full-color efficiency.

The multiple micro-structures each has a cross section of a ring shape. The multiple micro-structures each defines a first borehole and a second borehole. The second borehole has a size which is greater than that of the first borehole. The second borehole surrounds an outer side of the first borehole and is spaced apart from the first borehole in a predetermined distance. The multiple first boreholes each and the multiple second boreholes each extend through the second semiconductor layer and the light emitting layer in the stacking direction. The multiple first boreholes each and the multiple second boreholes each have opposite ends which are respectively closed by the first semiconductor layer and the current diffusion layer.

The light emitting layer includes multiple quantum well layers and multiple quantum barrier layers, which are alternately stacked in the stacking direction.

As an implementation, the multiple micro-structures each further includes a stopping wall formed between the first borehole and the second borehole, and the multiple quantum well layers each is separated by the micro-structure. A part of the quantum well layers disposed inside the stopping wall form blue indium gallium nitride (InGaN) quantum well layers, and a part of the quantum well layers disposed outside the micro-structures form green InGaN quantum well layers. The quantum dot is a red quantum dot and is excited to emit a red light, where a blue light and a green light emitted by a quantum well layer in the micro-structure and the red light, are synthesized to a white light.

Due to the part of the quantum well layers are independently separated and disposed inside the stopping wall, material stresses in the micro-structures are released, such that the part of the quantum well layers disposed inside the stopping wall emit blue lights by blue shifts of emission wavelengths, that is, original green light wavelengths change to blue light wavelengths, which form blue indium gallium nitride (InGaN) quantum well layers. While the part of the quantum well layers (i.e., green InGaN quantum well layers) not disposed inside the ring-shaped micro-structures still emit green lights, thus achieving multiple wavelengths emission. Based on the micro-structures, it may solve material stresses existed in the quantum well layers, then mitigate the quantum confined Stark effect (QCSE) resulted by the material stresses, thus improving recombination efficiency between electrons and currents.

The first borehole and the second borehole are in a shape of any one of a circle, a square, a rectangle, a triangle, or a rhombus.

The first borehole has a diameter ranging from 1 to 3 μm, and the second borehole has a diameter ranging from 7 to 13 μm when both the first borehole and the second borehole are in a circular shape.

The first borehole is formed in a laser drilling method, and the second borehole is formed in a laser sintering method.

The micro-structure is in a shape of any one of a cylinder, a cube, a cuboid, or a triangular prism.

The stopping wall is in a shape of any one of a hollow cylinder, a hollow cube, a hollow cuboid, or a hollow triangular prism.

The quantum well layer is a blue InGaN quantum well layer, and the quantum dot is a green quantum dot which is excited to emit a corresponding green light by absorbing a blue light.

As an implementation, the multiple quantum well layers are InGaN layers doped with aluminum, and the multiple quantum barrier layers are gallium nitride (GaN) layers. The current diffusion layer is made from a transparent conductive oxide (TCO) thin film material, and the first semiconductor layer is an N-type GaN layer doped with silicon. The second semiconductor layer is grown on the light emitting layer and is a P-type GaN layer doped with magnesium. The first contact electrode is an N-type ohmic contact electrode and made from titanate or aluminum. The second contact electrode is grown on the current diffusion layer and is a P-type ohmic contact electrode, where the second contact electrode is made from nickel or gold.

Based on the same inventive concept, a manufacturing method for a LED is provided in the disclosure. The method includes the following. A substrate layer is provided. A first semiconductor layer is grown on the substrate layer. A light emitting layer is grown on the first semiconductor layer. A second semiconductor layer is grown on the light emitting layer. Multiple micro-structures are manufactured in the light emitting layer and the second semiconductor layer and a quantum dot is filled in the micro-structure. A current diffusion layer and a second contact electrode are grown successively on the second semiconductor layer and the quantum dots are closed in the multiple micro-structures. The substrate layer is removed and a first contact electrode is plated on a location of the first semiconductor layer corresponding to the substrate layer.

In the LED, manufactured in the above-mentioned method, corresponding quantum dots are filled in borehole spaces defined in the micro-structures, and the corresponding quantum dots are excited, with a part of blue lights emitted by the micro-structures, to emit lights of corresponding colors, for example, red lights, or green lights, such that the light emitting layer may mix for white lights. Additionally, the corresponding quantum dots are filled in borehole spaces of the micro-structures, therefore, the micro-structures will improve color conversion efficiency due to a surface area effect, furthermore, improve full-color efficiency.

The light emitting layer includes multiple quantum well layers and multiple quantum barrier layers, which are alternately stacked. The multiple micro-structures are manufactured in the light emitting layer and the second semiconductor layer, and the quantum dot is filled in the micro-structure, which includes the following. A first borehole and a second borehole are defined. The first borehole extends through the light emitting layer and the second semiconductor layer in a stacking direction of the light emitting layer and the second semiconductor layer. The second borehole extends through the light emitting layer and the second semiconductor layer in a stacking direction of the light emitting layer and the second semiconductor layer, where the second borehole surrounds an outer side of the first borehole and is spaced apart from the first borehole in a predetermined distance. And the quantum dot is filled in the first borehole and the second borehole.

As an implementation, the multiple micro-structures each further includes a stopping wall formed between the first borehole and the second borehole, and the multiple quantum well layers each is separated by the micro-structures. A part of the quantum well layers disposed inside the stopping wall form blue indium gallium nitride (InGaN) quantum well layers, and a part of the quantum well layers disposed outside the multiple micro-structures form green InGaN quantum well layers. The quantum dot is a red quantum dot and is excited to emit a red light, where a blue light and a green light emitted by a quantum well layer in the micro-structure and the red light are synthesized to a white light.

Due to the part of the quantum well layers are independently separated and disposed inside the stopping wall, material stresses in the micro-structures are released, such that the part of the quantum well layers disposed inside the stopping wall emit blue lights by blue shifts of emission wavelengths, that is, original green light wavelengths change to blue light wavelengths, which form blue indium gallium nitride (InGaN) quantum well layers. While the part of the quantum well layers (i.e., green InGaN quantum well layers) not disposed inside the ring-shaped micro-structures still emit green lights, thus achieving multiple wavelengths emission. Based on the micro-structures, it may solve material stresses existed in the quantum well layers, then mitigate the quantum confined Stark effect (QCSE) due to material stresses, and thus improving recombination efficiency between electrons and currents.

The first borehole and the second borehole are in a shape of any one of a circle, a square, a rectangle, a triangle, or a rhombus.

The multiple micro-structures each is in a shape of any one of a cylinder, a cube, a cuboid, or a triangular prism.

As an implementation, the quantum well layer is a blue InGaN quantum well layer, and the quantum dot is a green quantum dot which is excited to emit a corresponding green light by absorbing a blue light.

Based on the same inventive concept, a display is provided in the disclosure. The display includes a display panel and multiple LEDs, where the multiple LEDs are fixed on the display panel and are electronically coupled with the display panel.

The display with the above-mentioned LEDs, corresponding quantum dots are filled in borehole spaces defined in multiple micro-structures, and the corresponding quantum dots are excited, with a part of blue lights emitted by the micro-structures, to emit lights of corresponding colors, for example, red lights, or green lights, such that the light emitting layer may mix for white lights. Additionally, the corresponding quantum dots are filled in borehole spaces of the micro-structures, therefore, the micro-structures will improve color conversion efficiency due to a surface area effect, furthermore, improve full-color efficiency, such that the display has a high resolution.

The multiple micro-structures each has a cross section of a ring shape. The multiple micro-structures each defines a first borehole and a second borehole. The second borehole has a size which is greater than that of the first borehole. The second borehole surrounds an outer side of the first borehole and is spaced apart from the first borehole in a predetermined distance. The multiple first boreholes each and the multiple second boreholes each extend through the second semiconductor layer and the light emitting layer in a stacking direction. The multiple first boreholes each and the multiple second boreholes each have opposite ends which are respectively closed by the first semiconductor layer and the current diffusion layer.

The light emitting layer includes multiple quantum well layers and multiple quantum barrier layers, which are alternately stacked in the stacking direction.

As an implementation, the multiple micro-structures each further includes a stopping wall formed between the first borehole and the second borehole, and the multiple quantum well layers each is separated by the micro-structure. A part of the quantum well layers disposed inside the stopping wall form blue indium gallium nitride (InGaN) quantum well layers, and a part of the quantum well layers disposed outside the micro-structures form green InGaN quantum well layers. The quantum dot is a red quantum dot and is excited to emit a red light, where a blue light and a green light emitted by a quantum well layer in the micro-structure and the red light are synthesized to a white light.

Due to the part of the quantum well layers are independently separated and disposed inside the stopping wall, material stresses in the micro-structures are released, such that the part of the quantum well layers disposed inside the stopping wall emit blue lights by blue shifts of emission wavelengths, that is, original green light wavelengths change to blue light wavelengths, which form blue indium gallium nitride (InGaN) quantum well layers. While the part of the quantum well layers (i.e., green InGaN quantum well layers) not disposed inside the ring-shaped micro-structures still emit green lights, thus achieving multiple wavelengths emission. Based on the micro-structures, it may solve material stresses existed in the quantum well layers, then mitigate the quantum confined Stark effect (QCSE) due to material stresses, and thus improving recombination efficiency between electrons and currents.

In the disclosure, corresponding quantum dots are filled in borehole spaces defined in multiple micro-structures, and lights of corresponding colors are emitted by exciting the corresponding quantum dots with a part of blue lights emitted by the micro-structures, for example, red lights, or green lights, such that a light emitting layer may mix for white lights. Additionally, the corresponding quantum dots are filled in borehole spaces of the micro-structures, therefore, the micro-structures will improve color conversion efficiency due to a surface area effect, furthermore, improve full-color efficiency.

A detailed content will be explained in the following implementations.

A layer structure of an epitaxial substrate in an LED and a specific process of a manufacturing method for the LED will be explained in detail in the disclosure.

FIG. 1 is a schematic cross-sectional view of a LED according to implementations. As illustrated in FIG. 1, an LED 100 is a gallium nitride (GaN) based micro-LED, which includes a first contact electrode 10, and further includes a first semiconductor layer 20, a light emitting layer 30, a second semiconductor layer 50, a current diffusion layer 60, and a second contact electrode 70 that are successively stacked on the first contact electrode 10. The first contact electrode 10 is in contact with and is connected with the first semiconductor layer 20, and the second contact electrode 70 is in contact with and is connected with the current diffusion layer 60.

In an implementation, the first contact electrode 10 may be an N-type ohmic contact electrode. In some implementations, the first contact electrode 10 may be made from metal materials such as titanate or aluminum. The second contact electrode 70 is grown on the current diffusion layer 60 and is a P-type ohmic contact electrode. In some implementations, the second contact electrode 70 may be made from metal materials such as nickel or gold.

In an implementation, the first semiconductor layer 20 may be a GaN layer, which is grown on the first contact electrode 10. A material of the first semiconductor layer 20 may be an N-type GaN series III-V group compound. In some implementations, the first semiconductor layer 20 may also be an N-type GaN layer doped with silicon. The second semiconductor layer 50 may be a GaN layer, which is grown on the light emitting layer 30. A material of the second semiconductor layer 50 may be a P-type GaN series III-V group compound. In some implementations, the second semiconductor layer 50 may also be a P-type GaN layer doped with magnesium.

In some implementations, the current diffusion layer 60 is made from a transparent conductive oxide (TCO) thin film material that has a high transmittance and a low resistivity in a visible spectral range. Exemplarily, the TCO thin film material mainly includes oxides, such as CdO, In2O3, SnO2, and ZnO, and their corresponding composite multiple compound semiconductor materials.

In this implementation, the light emitting layer 30 may be a light emitting layer, which is specifically grown by multiple quantum well layers 31 and multiple quantum barrier layers 33 that are alternately stacked. In some implementations, the multiple quantum well layers 31 may be indium gallium nitride (InGaN) layers doped with aluminum, and the multiple quantum barrier layers 33 may be GaN layers. In an implementation, the multiple quantum well layers 31 may be green InGaN quantum well layers 31a. The number of layers of the quantum well layers 31 in the light emitting layer 30 may be 20.

In an implementation, the LED further includes multiple micro-structures 80, which are disposed in the light emitting layer 30 and the second semiconductor layer 50, and between the first semiconductor layer 20 and the current diffusion layer 60. The multiple micro-structures 80 extend through the whole light emitting layer 30 in a stacking direction of the multiple quantum well layers 31. Exemplarily, the multiple micro-structures 80 may also extend through the whole second semiconductor layer 50 in the stacking direction of the multiple quantum well layers 31.

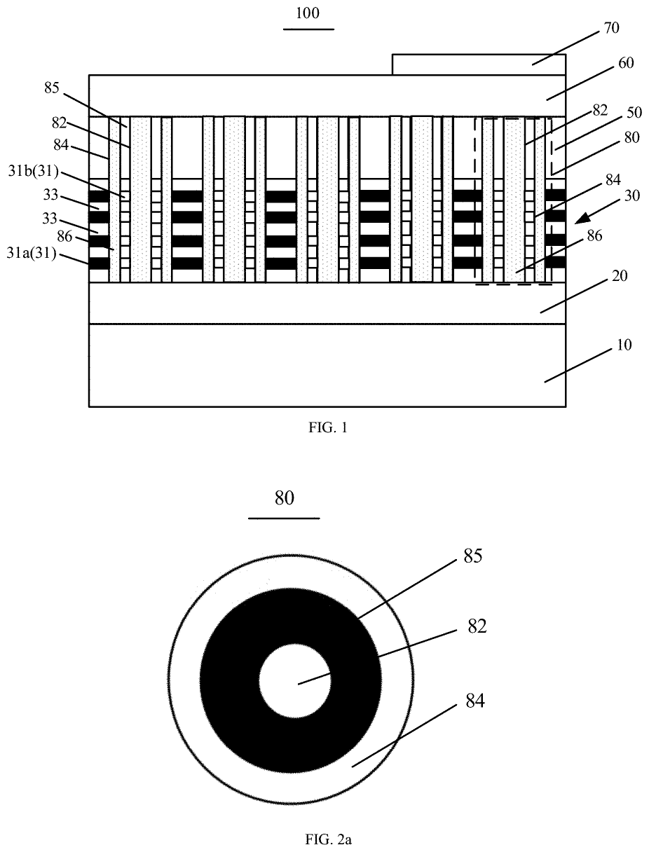

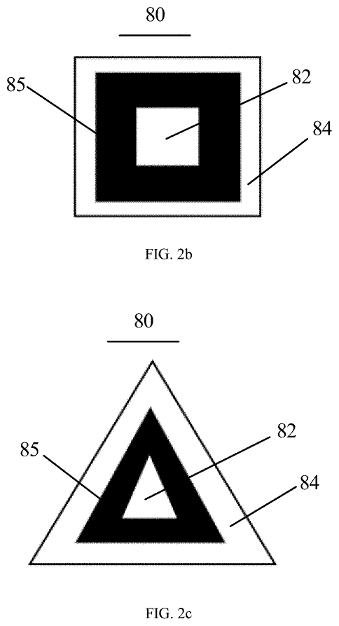

FIG. 2a is a schematic top view of a micro-structure 80 illustrated in FIG. 1 according to implementations. As illustrated in FIG. 2a, the multiple micro-structures 80 each is in a ring shape in a top view direction, and the multiple micro-structures 80 each defines a first borehole 82 and a second borehole 84. The first borehole 82 and the second borehole 84 have a same center, and the second borehole 84 has a size which is greater than that of the first borehole 82, i.e., the second borehole 84 is located around the first borehole 82. In this implementation, both the first borehole 82 and the second borehole 84 have a cross section of a circular shape, and a same circle center. The second borehole 84 has a radius which is greater than that of the first borehole 82, therefore, the first borehole 82 and the second borehole 84 form an annulus shape in the cross section.

In order to facilitate explaining and describing a location relation among the micro-structure 80, the light emitting layer 30, and the second semiconductor layer 50, reference can be further made to FIG. 1. The multiple first boreholes 82 each extends through the second semiconductor layer 50 and the light emitting layer 30 in the stacking direction of the quantum well layers 31. The multiple first boreholes 82 each has opposite ends which are respectively closed by the first semiconductor layer 20 and the current diffusion layer 60, i.e., the multiple first boreholes 82 are defined between the first semiconductor layer 20 and the current diffusion layer 60. The multiple second boreholes 84 each extends through the second semiconductor layer 50 and the light emitting layer 30 in the stacking direction of the quantum well layers 31. The multiple second boreholes 84 each has opposite ends which are respectively closed by the first semiconductor layer 20 and the current diffusion layer 60. The second borehole 84 surrounds an outer side of the first borehole 82 and is spaced apart from the first borehole 82 in a predetermined distance. The multiple second boreholes 84 are defined between the first semiconductor layer 20 and the current diffusion layer 60. Due to that the second borehole 84 is spaced apart from the first borehole 82 in the predetermined distance, a stopping wall 85 is formed between the second borehole 84 and the first borehole 82, where a thickness of the stopping wall 85 is a ring width of the annulus-shaped micro-structure 80. The stopping wall 85 is a ring-shaped wall formed by the light emitting layer 30 and the second semiconductor layer 50 in an extension direction of the first borehole 82 and the second borehole 84. The stopping wall 85 is configured to separate the first borehole 82 and the second borehole 84. Therefore, a material composition and a function of the stopping wall 85 in the light emitting layer 30 and the second semiconductor layer 50 have not changed.

In an implementation, the multiple quantum well layers 31 each is separated into multiple different parts due to existence of the first borehole 82 and the second borehole 84. More specifically, a part of the quantum well layers 31 are disposed outside the micro-structures 80, and other part of the quantum well layers 31 are independently disposed inside the stopping wall 85, i.e., the part of the quantum well layers 31 disposed outside the micro-structures 80 and the other part of the quantum well layers 31 disposed inside the stopping wall 85 are separated by the second boreholes 84, and the other part of the quantum well layers 31 disposed inside the stopping wall 85 are separated by the first boreholes 82. In the above-mentioned implementations, due to the other part of the quantum well layers 31 are independently separated and disposed inside the stopping wall 85, material stresses in the micro-structures 80 are released, such that the other part of the quantum well layers 31 disposed inside the stopping wall 85 emit blue lights by blue shifts of emission wavelengths, that is, original green light wavelengths change to blue light wavelengths, which form blue InGaN quantum well layers 31b. While the part of the quantum well layers (i.e., the green InGaN quantum well layers 31a) not disposed inside the ring-shaped micro-structures 80 still emit green lights, thus achieving multiple wavelengths emission. Based on the micro-structures 80, it may solve material stresses existed in the quantum well layers 31, then mitigate the quantum confined Stark effect (QCSE) due to material stresses, and thus improving recombination efficiency between electrons and currents.

In an implementation, the LED 100 further includes a quantum dot 86 filled in the first borehole 82 and the second borehole 84. In the above-mentioned implementations, the quantum dot 86 may be filled in the first borehole 82 and the second borehole 84 by using a spray machine in a spraying method. In an implementation, the quantum dot 86 is a red quantum dot and is excited to emit a red light, where a blue light and a green light emitted by a quantum well layer 31 in the micro-structures 80 and the red light are synthesized to a white light.

It should be understood that, in some implementations, the quantum dot 86 may also be a green quantum dot. At this time, the green quantum dot is directly filled in each of the multiple micro-structures 80, and the quantum well layer 31 is a blue InGaN quantum well layer and can emit the blue light. The green quantum dot emits a green light of a corresponding peak wavelength by absorbing the blue light.

As mentioned above, in the disclosure, corresponding quantum dots 86 are filled in borehole spaces formed in the micro-structures 80 of the LED, and the corresponding quantum dots 86 are excited with a part of blue lights emitted by the micro-structures 80, to emit red lights or green lights, such that the light emitting layer 30 may mix for white lights. Additionally, the corresponding quantum dots 86 are filled in borehole spaces of the micro-structures 80, therefore, the micro-structures 80 will improve color conversion efficiency due to a surface area effect, furthermore, improve full-color efficiency.

In some implementations, when both the first borehole 82 and the second borehole 84 have a cross section of an annulus shape, the thickness of the stopping wall 85 may be less than or equal to 5 μm, such as 3-5 μm, or 3 μm, 4 μm, 5 μm, or other thicknesses.

In some implementations, the first borehole 82 is formed in a laser drilling method, and the second borehole 84 is formed in a laser sintering method. The first borehole 82 and the second borehole 84 are in a shape of any one of a circle, a square, a rectangle, a triangle, or a rhombus.

In some implementations, the first borehole 82 and the second borehole 84 have a cross section of a shape which is not limited to an annulus shape (as illustrated in FIG. 2a). In other implementations, the first borehole 82 and the second borehole 84 have the cross section of a shape which may be a square annulus shape (as illustrated in FIG. 2b), a triangle annulus shape (as illustrated in FIG. 2c), a rectangle annulus shape, or other shapes. Correspondingly, the whole micro-structure 80 is in a shape which may be a cylinder, a cube, a cuboid, a triangular prism, or other shapes. It should be understood that, the whole stopping wall 85 is in a shape which may be a hollow cylinder, a hollow cube, a hollow cuboid, a hollow triangular prism, or other shapes, i.e., the stopping wall 85 has a cross section of a shape which may be an annulus shape, a square annulus shape, a rectangle annulus shape, a triangle annulus shape, or other shapes.

In some implementations, when both the first borehole 82 and the second borehole 84 have a cross section of a circular shape, the micro-structure 80 has a size of an inner diameter (i.e., a diameter of the first borehole 82) which may be less than or equal to 3 μm, such as 1-3 μm, or 1 μm, 2 μm, 3 μm, or other sizes. Correspondingly, the micro-structure 80 has a size of an outer diameter (i.e., a diameter of the second borehole 84) which may be less than or equal to 13 μm, such as 7-13 μm, or 7 μm, 8 μm, 9 μm, 10 μm, 11 μm, or other sizes.

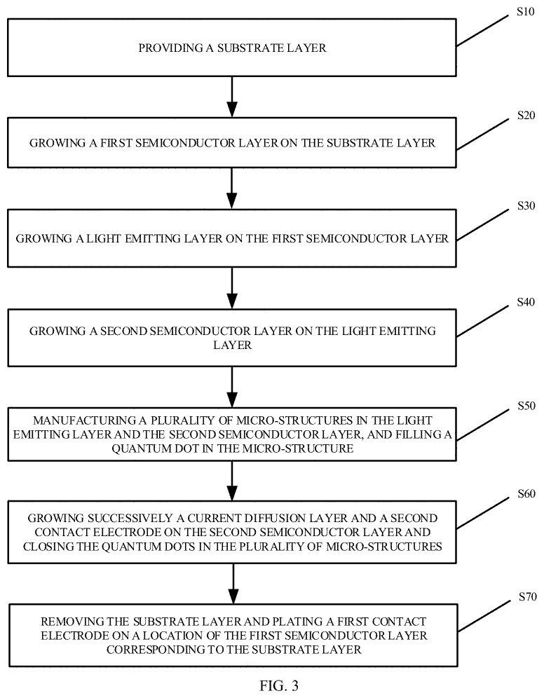

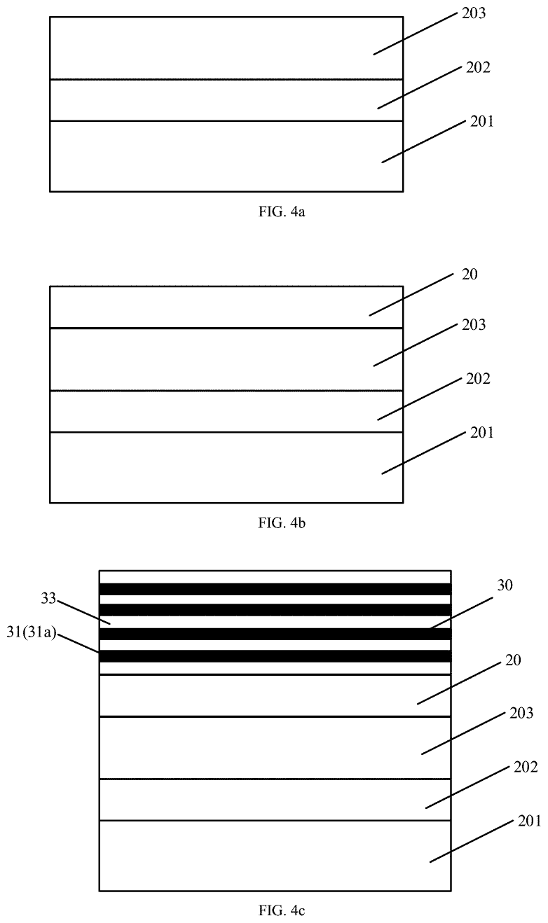

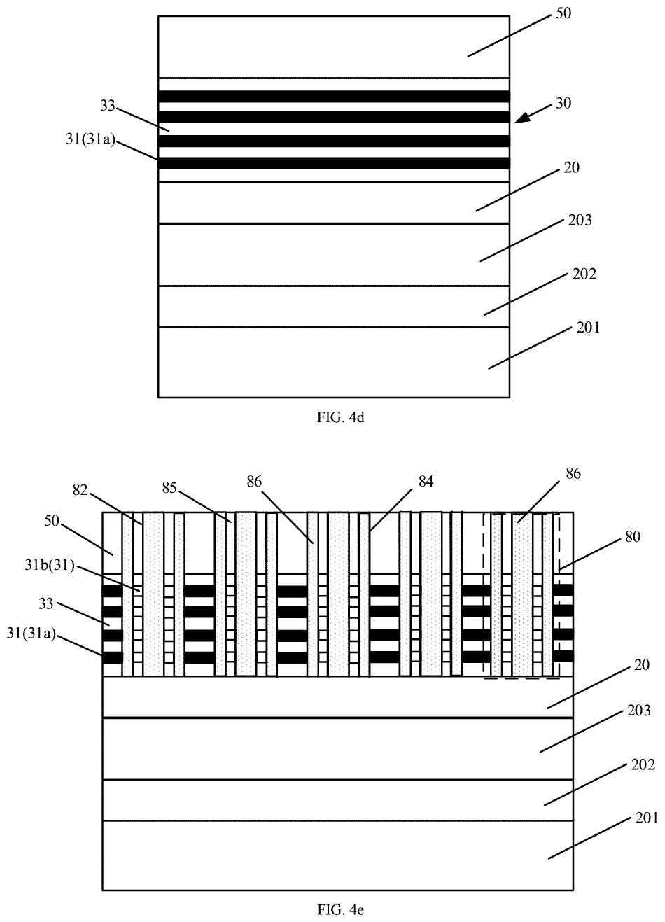

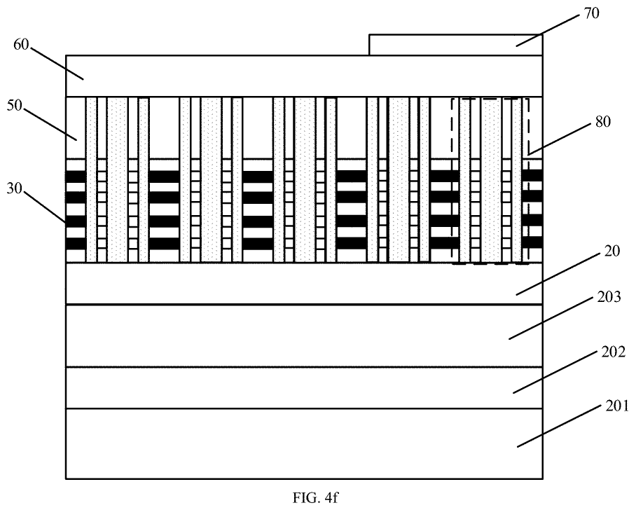

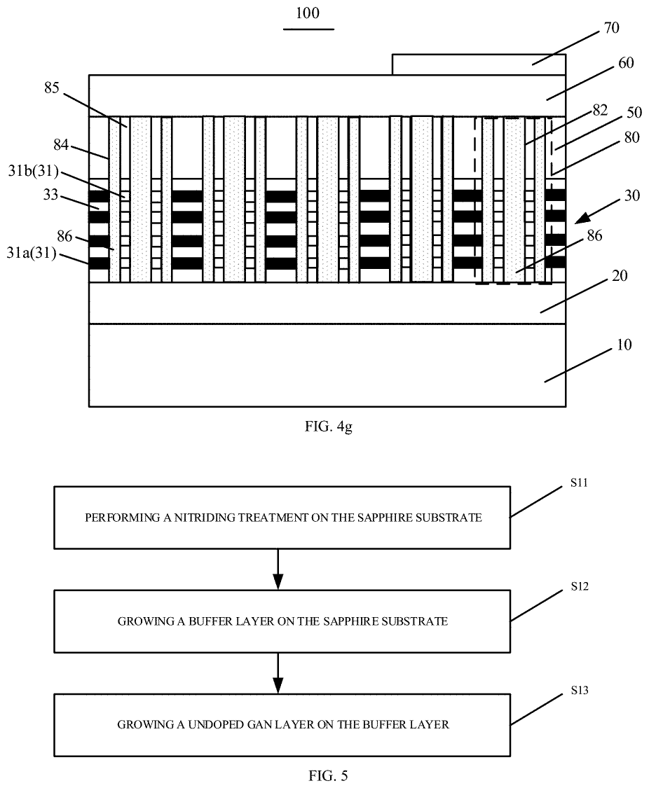

FIG. 3 is a schematic flowchart illustrating a manufacturing method for the LED of FIG. 1. FIG. 4a-FIG. 4g are schematic structural diagrams corresponding to operations in the manufacturing method of FIG. 3. Reference can be FIG. 3 and FIG. 4a-FIG. 4g together. The LED 100 is the gallium nitride (GaN) based micro-LED, which includes the first contact electrode 10, and includes the first semiconductor layer 20, the light emitting layer 30, the second semiconductor layer 50, the current diffusion layer 60, and the second contact electrode 70 that are successively stacked on the first contact electrode 10. The first contact electrode 10 is in contact with and is connected with the first semiconductor layer 20, and the second contact electrode 70 is in contact with and is connected with the current diffusion layer 60. The manufacturing method includes at least the following operations.

At block S10, a substrate layer is provided.

Specifically, as illustrated in FIG. 4a, the substrate layer includes a sapphire substrate 201, a buffer layer 202, and a undoped GaN layer 203 which are successively stacked. The buffer layer 202 is located between the sapphire substrate 201 and the undoped GaN layer 203. In some implementations, the sapphire substrate 201 may be a crystal orientation sapphire, and the buffer layer 202 may be a GaN buffer layer or a low temperature GaN (LT-GaN) buffer layer.

In an implementation, as illustrated in FIG. 5, operations at block S10 include the following sub-operations S11-S13.

At block S11, a nitriding treatment is performed on the sapphire substrate 201.

It should be understood that operations at block S11 can clean a surface of the sapphire substrate 201.

At block S12, the buffer layer 202 is grown on the sapphire substrate 201.

At block S13, the undoped GaN layer 203 is grown on the buffer layer 202.

In some implementations, after operations at block S12, the buffer layer will be performed an in situ thermal anneal.

At block S20, the first semiconductor layer 20 is grown on the substrate layer.

Specifically, as illustrated in FIG. 4b, the first semiconductor layer 20 is grown on the undoped GaN layer 203 of the substrate layer. In an implementation, the first semiconductor layer 20 may be the GaN layer. The material of the first semiconductor layer 20 may be the N-type GaN series III-V group compound. In some implementations, the first semiconductor layer 20 may also be the N-type GaN layer doped with silicon.

At block S30, the light emitting layer 30 is grown on the first semiconductor layer 20.

Specifically, as illustrated in FIG. 4c, the light emitting layer 30 is grown on the first semiconductor layer 20. In an implementation, the light emitting layer 30 may be a light emitting layer, which is specifically grown by the multiple quantum well layers 31 and the multiple quantum barrier layers 33 that are alternately stacked. In some implementations, the multiple quantum well layers 31 may be InGaN layers doped with aluminum, and the multiple quantum barrier layers 33 may be GaN layers. In an implementation, the multiple quantum well layers 31 may be green InGaN quantum well layers 31a. The number of layers of the quantum well layers 31 in the light emitting layer 30 may be 20.

At block S40, the second semiconductor layer 50 is grown on the light emitting layer 30.

Specifically, as illustrated in FIG. 4d, the second semiconductor layer 50 is grown on the light emitting layer 30. In an implementation, the second semiconductor layer 50 is grown on the light emitting layer 30. The second semiconductor layer 50 may be the GaN layer. The material of the second semiconductor layer 50 may be the P-type GaN series III-V group compound. In some implementations, the second semiconductor layer 50 may also be the P-type GaN layer doped with magnesium.

At block S50, the multiple micro-structures 80 are manufactured in the light emitting layer 30 and the second semiconductor layer 50, and the quantum dot 86 is filled in each of the multiple micro-structures 80.

Specifically, as illustrated in FIG. 4e, in an implementation, the multiple micro-structures 80 are disposed in the light emitting layer 30 and the second semiconductor layer 50. The multiple micro-structures 80 extend through the whole light emitting layer 30 and the whole second semiconductor layer 50 in the stacking direction of the multiple quantum well layers 31. The multiple micro-structures 80 each is in a ring shape in a top view direction, and the multiple micro-structures 80 each defines a first borehole 82 and a second borehole 84. The first borehole 82 and the second borehole 84 have a same center and the second borehole 84 has a size which is greater than that of the first borehole 82, i.e., the second borehole 84 is located around the first borehole 82. In an implementation, as illustrated in FIG. 2a, both the first borehole 82 and the second borehole 84 have the cross section of the circular shape, and the same circle center. The second borehole 84 has the radius which is greater than that of the first borehole 82, therefore, the first borehole 82 and the second borehole 84 have the cross section in the annulus shape. In some implementations, the shape of the cross section of the first borehole 82 and the second borehole 84 may be a square annulus shape (as illustrated in FIG. 2b), a triangle annulus shape (as illustrated in FIG. 2c), a rectangle annulus shape, or other shapes. Correspondingly, the shape of the whole micro-structure 80 may be a cylinder, a cube, a cuboid, a triangular prism, or other shapes.

The multiple first boreholes 82 each extends through the second semiconductor layer 50 and the light emitting layer 30 in the stacking direction of the multiple quantum well layers 31, and the multiple second boreholes 84 each extends through the second semiconductor layer 50 and the light emitting layer 30 in the stacking direction of the multiple quantum well layers 31. And the second borehole 84 surrounds an outer side of the first borehole 82 and is spaced apart from the first borehole 82 in a predetermined distance. Due to that the second borehole 84 is spaced apart from the first borehole 82 in the predetermined distance, a stopping wall 85 is formed between the second borehole 84 and the first borehole 82, where a thickness of the stopping wall 85 is a ring width of the annulus-shaped micro-structure 80. The stopping wall 85 is a ring-shaped wall formed by the light emitting layer 30 and the second semiconductor layer 50 in an extension direction of the first borehole 82 and the second borehole 84. The stopping wall 85 is configured to separate the first borehole 82 and the second borehole 84. Therefore, a material composition and a function of the stopping wall 85 in the light emitting layer 30 and the second semiconductor layer 50 have not changed.

It should be understood that, the whole stopping wall 85 is in a shape which may be a hollow cylinder, a hollow cube, a hollow cuboid, a hollow triangular prism, or other shapes, i.e., the stopping wall 85 has a cross section of a shape which may be an annulus shape, a square annulus shape, a rectangle annulus shape, a triangle annulus shape, or other shapes.

In an implementation, the multiple quantum well layers 31 each is separated into multiple different parts due to existence of the first borehole 82 and the second borehole 84. More specifically, a part of the quantum well layers 31 are disposed outside the micro-structures 80, and other part of the quantum well layers 31 are independently disposed inside the stopping wall 85, i.e., the part of the quantum well layers 31 disposed outside the micro-structures 80 and the other part of the quantum well layers 31 disposed inside the stopping wall 85 are separated by the second boreholes 84, and the other part of the quantum well layers 31 disposed inside the stopping wall 85 are separated by the first boreholes 82. In the above-mentioned implementations, due to the other part of the quantum well layers 31 are independently separated and disposed inside the stopping wall 85, material stresses in the micro-structures 80 are released, such that the other part of the quantum well layers 31 disposed inside the stopping wall 85 emit blue lights by blue shifts of emission wavelengths, that is, original green light wavelengths change to blue light wavelengths, which form blue InGaN quantum well layers 31b. While the part of the quantum well layers (i.e., green InGaN quantum well layers 31a) not disposed inside the ring-shaped micro-structures 80 still emit green lights, thus achieving multiple wavelengths emission. Based on the micro-structures 80, it may solve material stresses existed in the quantum well layers 31, then mitigate the quantum confined Stark effect (QCSE) due to material stresses, and thus improving recombination efficiency between electrons and currents.

In the above-mentioned implementations, the quantum dot 86 may be filled in the first borehole 82 and the second borehole 84 by using a spray machine in a spraying method. In an implementation, the quantum dot 86 is a red quantum dot and is excited to emit a red light, where a blue light and a green light emitted by a quantum well layer 31 in the micro-structure 80 and the red light are synthesized to a white light.

It should be understood that, in some implementations, the quantum dot 86 may also be a green quantum dot. At this time, the green quantum dot is directly filled in each of the multiple micro-structures 80, and the quantum well layer 31 is a blue InGaN quantum well layer and can emit a blue light. The green quantum dot emits a green light of a corresponding peak wavelength by absorbing the blue light.

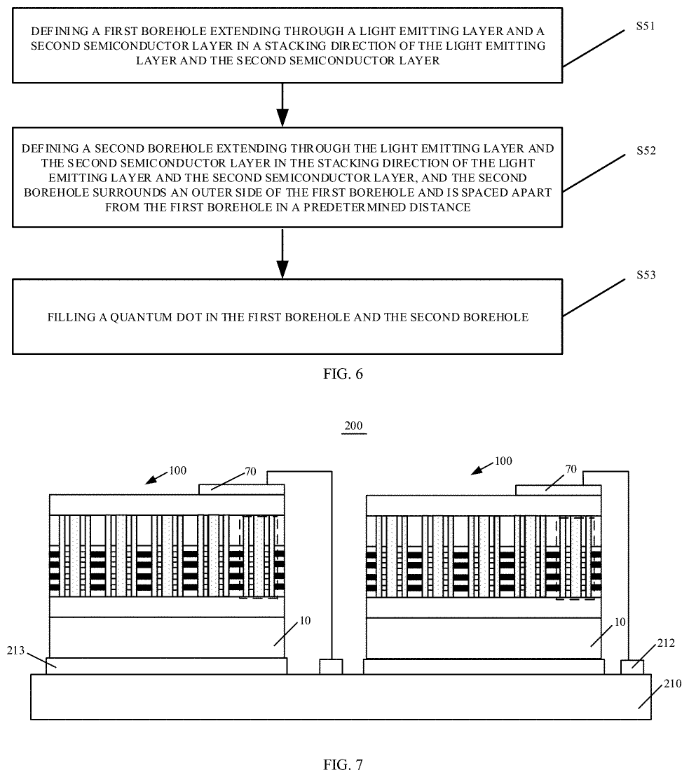

In an implementation, as illustrated in FIG. 6, operations at block S50 include the following sub-operations S51-S53.

At block S51, the first borehole 82 is defined extending through the light emitting layer 30 and the second semiconductor layer 50 in the stacking direction of the light emitting layer 30 and the second semiconductor layer 50.

At block S52, the second borehole 84 is defined extending through the light emitting layer 30 and the second semiconductor layer 50 in the stacking direction of the light emitting layer 30 and the second semiconductor layer 50. The second borehole 84 surrounds an outer side of the first borehole 82 and is spaced apart from the first borehole 82 in a predetermined distance.

At block S53, the quantum dot is filled in the first borehole 82 and the second borehole 84.

In some implementations, when both the first borehole 82 and the second borehole 84 have a cross section of an annulus shape, a thickness of the stopping wall 85 may be less than or equal to 5 μm, such as 3-5 μm, or 3 μm, 4 μm, 5 μm, or other thicknesses.

In some implementations, the first borehole 82 is formed in a laser drilling method, and the second borehole 84 is formed in a laser sintering method. The first borehole 82 and the second borehole 84 are in a shape of any one of a circle, a square, a rectangle, a triangle, or a rhombus.

In some implementations, when both the first borehole 82 and the second borehole 84 have a cross section of a circular shape, the micro-structure 80 has a size of an inner diameter (i.e., a diameter of the first borehole 82) which may be less than or equal to 3 μm, such as 1-3 μm, or 1 μm, 2 μm, 3 μm, or other sizes. Correspondingly, the micro-structure 80 has a size of an outer diameter (i.e., a diameter of the second borehole 84) which may be less than or equal to 13 μm, such as 7-13 μm, or 7 μm, 8 μm, 9 μm, 10 μm, 11 μm, or other sizes.

At block S60, the current diffusion layer 60 and the second contact electrode 70 are grown successively on the second semiconductor layer 50, and the quantum dots 86 are closed in the multiple micro-structures 80.

Specifically, as illustrated in FIG. 4f, the current diffusion layer 60 and the second contact electrode 70 are grown successively on the second semiconductor layer 50, and the quantum dots 86 are closed in the multiple micro-structures 80. In some implementations, the current diffusion layer 60 is made from a transparent conductive oxide (TCO) thin film material that has a high transmittance and a low resistivity in a visible spectral range. Exemplarily, the TCO thin film material mainly includes oxides, such as CdO, In2O3, SnO2, and ZnO and their corresponding composite multiple compound semiconductor materials. In an implementation, the second contact electrode 70 is grown on the current diffusion layer 60 and is a P-type ohmic contact electrode. In some implementations, the second contact electrode 70 may be made from metal materials such as nickel or gold.

At block S70, the substrate layer is removed, and the first contact electrode 10 is plated on a location of the first semiconductor layer 20 corresponding to the substrate layer.

Specifically, as illustrated in FIG. 4g, after growing successively the current diffusion layer 60 and the second contact electrode 70 on the second semiconductor layer 50, the substrate layer is lifted off from the first semiconductor layer 20 in a laser lift off (LLO) process, to complete lifting off the substrate layer. Thereafter, the first contact electrode 10 is plated on the original location of the substrate layer, i.e., the first contact electrode 10 is plated on a side of the first semiconductor layer 20 opposite to the light emitting layer 30, thus completing manufacturing the LED 100.

In an implementation, the first contact electrode 10 may be an N-type ohmic contact electrode. In some implementations, the first contact electrode 10 is made from metal materials such as titanate or aluminum.

In the above-mentioned implementations, methods for growing materials in the above-mentioned operations mainly include a metal-organic chemical vapor deposition (MOCVD) method, a molecular beam epitaxy (MBE) method, or the like.

As mentioned above, in the LED 100 formed in the manufacturing method of the disclosure, corresponding quantum dots 86 are filled in borehole spaces defined in the micro-structures 80, and the corresponding quantum dots 86 are excited with a part of blue lights emitted by the micro-structures 80, to emit red lights, or green lights, such that the light emitting layer 30 may mix for white lights. Additionally, the corresponding quantum dots 86 are filled in borehole spaces of the micro-structures 80, therefore, the micro-structures 80 will improve color conversion efficiency due to a surface area effect, furthermore, improve full-color efficiency.

FIG. 7 is a schematic cross-sectional view of a display with the above-mentioned LED according to implementations. In an implementation, as illustrated in FIG. 7, a display 200 includes a display panel 210 and multiple LEDs 100. The multiple LEDs 100 are fixed on the display panel 210 and are electronically coupled with the display panel 210. Corresponding quantum dots 86 are filled in borehole spaces defined in the micro-structures 80, and when the display 200 is working, the corresponding quantum dots 86 are excited with a part of blue lights emitted by the micro-structures 80 to emit lights of corresponding colors, for example, red lights, or green lights, such that the light emitting layer 30 may mix for white lights. Therefore, the display 200 can provide a white light source.

In some implementations, the display panel 210 may be disposed with multiple sets of anode and cathode gaskets or anode and cathode bonding pads, and this implementation is illustrated with the anode and cathode bonding pads as examples. In this implementation, each set of anode and cathode bonding pads includes an anode bonding pad 212 and a cathode bonding pad 213, which are separated from each other. The first contact electrode 10 of each of the multiple LEDs 100 is directly contacted with the cathode bonding pad 213, such that the first contact electrode 10 is electronically coupled with the cathode bonding pad 213. The second contact electrode 70 of each of the multiple LEDs 100 is electronically coupled with the anode bonding pad 212.

In the above-mentioned implementations, the display 200 may be an augmented reality (AR) micro-display or a mobile/large display.

As mentioned above, in the disclosure, in the display 200 with the above-mentioned LEDs 100, corresponding quantum dots 86 are filled in borehole spaces defined in the micro-structures 80, and the corresponding quantum dots 86 are excited with a part of blue lights emitted by the micro-structures 80, to emit red lights, or green lights, such that the light emitting layer 30 may mix for white lights. Additionally, the corresponding quantum dots 86 are filled in borehole spaces of the micro-structures 80, therefore, the micro-structures 80 will improve color conversion efficiency due to a surface area effect, furthermore, improve full-color efficiency, such that the display 200 has a high resolution.

While the disclosure has been described in connection with certain implementations, it is to be understood that the disclosure is not to be limited to the disclosed implementations but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. A light-emitting diode (LED), comprising:
a first semiconductor layer, a light emitting layer, a second semiconductor layer, and a current diffusion layer that are successively stacked;
a first contact electrode which is in contact with and is connected with the first semiconductor layer;
a second contact electrode which is in contact with and is connected with the current diffusion layer;
a plurality of micro-structures extending through the light emitting layer and the second semiconductor layer in a stacking direction of the light emitting layer and the second semiconductor layer, wherein the plurality of micro-structures each defines a borehole space, wherein the borehole space has opposite ends which are respectively closed by the first semiconductor layer and the current diffusion layer; and
a quantum dot filled in the borehole space of each of the plurality of micro-structures.

2. The LED of claim 1, wherein
the plurality of micro-structures each has a cross section of a ring shape;
the plurality of micro-structures each defines a first borehole and a second borehole, the second borehole has a size which is greater than that of the first borehole, and the second borehole surrounds an outer side of the first borehole and is spaced apart from the first borehole in a predetermined distance; and
the plurality of first boreholes each and the plurality of second boreholes each extend through the second semiconductor layer and the light emitting layer in the stacking direction, and the plurality of first boreholes each and the plurality of second boreholes each have opposite ends which are respectively closed by the first semiconductor layer and the current diffusion layer.

3. The LED of claim 2, wherein the light emitting layer comprises a plurality of quantum well layers and a plurality of quantum barrier layers, which are alternately stacked in the stacking direction.

4. The LED of claim 3, wherein
the plurality of micro-structures each further comprises a stopping wall formed between the first borehole and the second borehole, and the plurality of quantum well layers each is separated by the micro-structure;
a part of the quantum well layers disposed inside the stopping wall form blue indium gallium nitride (InGaN) quantum well layers, and a part of the quantum well layers disposed outside the micro-structures form green InGaN quantum well layers.

5. The LED of claim 2, wherein the first borehole and the second borehole are in a shape of any one of a circle, a square, a rectangle, a triangle, or a rhombus.

6. The LED of claim 5, wherein when both the first borehole and the second borehole are in the circular shape, the first borehole has a diameter ranging from 1 to 3 μm, and the second borehole has a diameter ranging from 7 to 13 μm.

7. The LED of claim 2, wherein the first borehole is formed in a laser drilling method, and the second borehole is formed in a laser sintering method.

8. The LED of claim 2, wherein the micro-structure is in a shape of any one of a cylinder, a cube, a cuboid, or a triangular prism.

9. The LED of claim 4, wherein the quantum dot is a green quantum dot or a red quantum dot.

10. The LED of claim 3, wherein
the plurality of quantum well layers are indium gallium nitride (InGaN) layers doped with aluminum, and the plurality of quantum barrier layers are gallium nitride (GaN) layers;
the current diffusion layer is made from a transparent conductive oxide (TCO) thin film material, the first semiconductor layer is an N-type GaN layer doped with silicon, and the second semiconductor layer is grown on the light emitting layer and is a P-type GaN layer doped with magnesium;
the first contact electrode is an N-type ohmic contact electrode and made from titanate or aluminum; and
the second contact electrode is grown on the current diffusion layer and is a P-type ohmic contact electrode, wherein the second contact electrode is made from nickel or gold.

11. The LED of claim 4, wherein the stopping wall is in a shape of any one of a hollow cylinder, a hollow cube, a hollow cuboid, or a hollow triangular prism.

12. A manufacturing method for a light-emitting diode (LED), comprising:
providing a substrate layer;
growing a first semiconductor layer on the substrate layer;
growing a light emitting layer on the first semiconductor layer;
growing a second semiconductor layer on the light emitting layer;
manufacturing a plurality of micro-structures in the light emitting layer and the second semiconductor layer, and filling a quantum dot in the micro-structure;
growing successively a current diffusion layer and a second contact electrode on the second semiconductor layer and closing the quantum dots in the plurality of micro-structures; and
removing the substrate layer and plating a first contact electrode on a location of the first semiconductor layer corresponding to the substrate layer.

13. The manufacturing method of claim 12, wherein
the light emitting layer comprises a plurality of quantum well layers and a plurality of quantum barrier layers, which are alternately stacked;
manufacturing the plurality of micro-structures in the light emitting layer and the second semiconductor layer, and filling the quantum dot in the micro-structure, comprising:
defining a first borehole extending through the light emitting layer and the second semiconductor layer in a stacking direction of the light emitting layer and the second semiconductor layer;
defining a second borehole extending through the light emitting layer and the second semiconductor layer in the stacking direction of the light emitting layer and the second semiconductor layer, wherein the second borehole surrounds an outer side of the first borehole and is spaced apart from the first borehole in a predetermined distance; and
filling the quantum dot in the first borehole and the second borehole.

14. The manufacturing method of claim 13, wherein
the plurality of micro-structures each further comprises a stopping wall formed between the first borehole and the second borehole, and the plurality of quantum well layers each is separated by the micro-structure;
a part of the quantum well layers disposed inside the stopping wall form blue indium gallium nitride (InGaN) quantum well layers, and a part of the quantum well layers disposed outside the micro-structures form green InGaN quantum well layers; and
the quantum dot is a red quantum dot, and emits a red light by exciting the quantum dot, wherein a blue light and a green light emitted by a quantum well layer in the micro-structures and the red light are synthesized to a white light.

15. The manufacturing method of claim 13, wherein
the plurality of micro-structures each further comprises a stopping wall formed between the first borehole and the second borehole, and the plurality of quantum well layers each is separated by the micro-structure;
a part of the quantum well layers disposed inside the stopping wall form blue indium gallium nitride (InGaN) quantum well layers, and a part of the quantum well layers disposed outside the micro-structures form green InGaN quantum well layers; and
the quantum dot is a green quantum dot.

16. The manufacturing method of claim 13, wherein a first borehole and a second borehole are in a shape of any one of a circle, a square, a rectangle, a triangle, or a rhombus.

17. The manufacturing method of claim 12, wherein the micro-structure is in a shape of any one of a cylinder, a cube, a cuboid, or a triangular prism.

18. A display, comprising:
a display panel and a plurality of light-emitting diodes (LEDs), wherein the plurality of LEDs are fixed on the display panel and are electronically coupled with the display panel; and
the plurality of LEDs each comprising:
a first semiconductor layer, a light emitting layer, a second semiconductor layer, and a current diffusion layer that are successively stacked;
a first contact electrode which is in contact with and is connected with the first semiconductor layer;
a second contact electrode which is in contact with and is connected with the current diffusion layer;
a plurality of micro-structures extending through the light emitting layer and the second semiconductor layer in a stacking direction of the light emitting layer and the second semiconductor layer, wherein the plurality of micro-structures each defines a borehole space, wherein the borehole space has opposite ends which are respectively closed by the first semiconductor layer and the current diffusion layer; and
a quantum dot filled in the borehole space of each of the plurality of micro-structures.

19. The display of claim 18, wherein
the plurality of micro-structures each has a cross section of a ring shape;
the plurality of micro-structures each defines a first borehole and a second borehole, the second borehole has a size which is greater than that of the first borehole, the second borehole surrounds an outer side of the first borehole and is spaced apart from the first borehole in a predetermined distance; and
the plurality of first boreholes each and the plurality of second boreholes each extend through the second semiconductor layer and the light emitting layer in the stacking direction, and the plurality of first boreholes each and the plurality of second boreholes each have opposite ends which are respectively closed by the first semiconductor layer and the current diffusion layer.

20. The display of claim 19, wherein
the light emitting layer comprises a plurality of quantum well layers and a plurality of quantum barrier layers, which are alternately stacked in the stacking direction,
the plurality of micro-structures each further comprises a stopping wall formed between the first borehole and the second borehole, and the plurality of quantum well layers each is separated by the micro-structures;
a part of the quantum well layers disposed inside the stopping wall form blue indium gallium nitride (InGaN) quantum well layers, and a part of the quantum well layers disposed outside the micro-structures form green InGaN quantum well layers; and
the quantum dot is a red quantum dot.
